(19) United States
(12) Patent Application Publication
(10) Pub. No.: US 2017/0075180 A1
(43) Pub. Date: Mar. 16, 2017

(54) Array Substrate and Manufacturing Method Thereof, Display Panel and Display Device

(71) Applicants: BOE Technology Group Co., Ltd., Beijing (CN); Hefei Xinsheng Optoelectronics Technology Co., Ltd., Anhui (CN)

(72) Inventors: Meixu Wang, Beijing (CN); Song Wu, Beijing (CN); Chao Dai, Beijing (CN); Jianhui Li, Beijing (CN)

(21) Appl. No.: 15/146,264

(22) Filed: May 4, 2016

(30) Foreign Application Priority Data
Sep. 16, 2015 (CN) 201510591070.3

(51) Int. Cl. G02F 1/1362; G02F 1/1337; G02F 1/1333; H01L 27/12

(52) U.S. Cl. CPC G02F 1/136286; H01L 27/124; H01L 27/1259; G02F 1/1337; G02F 1/133345; G02F 1/133784; G02F 2001/136254

(57) ABSTRACT

An array substrate and a manufacturing method thereof, a display panel and a display device are provided. The array substrate comprises a base substrate, and a test pad and an alignment film which are formed on the base substrate. A groove is provided on a surface of the test pad, and an extending direction of the groove is consistent with a rubbing direction of the alignment film.

This application claims priority to and the benefit of Chinese Patent Application No. 201510591070.3 filed on Sep. 16, 2015, which application is incorporated herein in its entirety.

### TECHNICAL FIELD

Embodiments of the present disclosure relate to an array substrate and a manufacturing method thereof, a display panel and a display device.

### BACKGROUND

Liquid Crystal Display (TFT-LCD) has advantages of high display quality, low power consumption and no radiation, develops very fast in recent years and is widely used in various fields.

The liquid crystal display mainly comprises an array substrate, a color filter substrate and a liquid crystal layer. Generally, performances of a manufactured array substrate need to be tested. For example, in the case that electrical properties of the array substrate are tested, a Shorting Bar technique is used in order to reduce a number of test pads. However, the test pads adopting the Shorting Bar technique are large in area and higher in height, and in the case that a subsequent alignment film rubbing process is performed, these test pads are likely to damage a rubbing cloth for performing the rubbing process and lead to a poor rubbing effect.

### SUMMARY

According to embodiments of the disclosure, an array substrate is provided. The array substrate comprises a base substrate, and a test pad and an alignment film which are formed on the base substrate. A groove is provided on a surface of the test pad and an extending direction of the groove is consistent with a rubbing direction of the alignment film.

For example, the test pad includes a first conducting layer, an insulating layer and a second conducting layer which are formed on the base substrate, the second conducting layer is electrically connected with the first conducting layer through via holes in the insulating layer.

For example, the first conducting layer includes a plurality of parallel conducting strips and a thickness of the insulating layer and a thickness of the second conducting layer are uniform, so as to form the groove on the surface of the test pad.

For example, the test pad is formed in a non-display region of the array substrate; a display region of the array substrate includes a gate line, a first protective layer and a pixel electrode which are formed on the base substrate; and the first conducting layer and the gate line are made of a same material and provided in a same layer, the insulating layer and the first protective layer are made of a same material and provided in a same layer, and the second conducting layer and the pixel electrode are made of a same material and provided in a same layer.

For example, the test pad is connected with the gate line and configured to test the gate line.

For example, the test pad is formed in a non-display region of the array substrate; a display region of the array substrate includes a data line, a second protective layer and a pixel electrode which are formed on the base substrate; and the first conducting layer and the data line are made of a same material and provided in a same layer, the insulating layer and the second protective layer are made of a same material and provided in a same layer, and the second conducting layer and the pixel electrode are made of a same material and provided in a same layer.

For example, the test pad is connected with the data line and configured to test the data lines.

For example, the test pad includes a conducting layer, and a partial region of the conducting layer is thinned to form the groove.

For example, the test pad is formed in a non-display region of the array substrate; a display region of the array substrate includes a gate line provided on the base substrate; and the conducting layer and the gate line are made of a same material and provided in a same layer.

For example, the test pad is connected with the gate line and configured to test the gate line.

For example, the test pad is formed in a non-display region of the array substrate; a display region of the array substrate includes a data line provided on the base substrate; and the conducting layer and the data line are made of a same material and provided in a same layer.

For example, the test pad is connected with the data line and configured to test the data line.

According to the embodiments of the disclosure, a display panel is provided. The display panel comprises the array substrate as described above.

According to the embodiments of the disclosure, a display device is provided. The display device comprises the display panel as described above.

According to the embodiments of the disclosure, a manufacturing method of an array substrate is provided. The method comprises: forming a test pad on a base substrate, wherein a groove is formed on a surface of the test pad; and forming an alignment film on the base substrate, wherein a rubbing direction of the alignment film is consistent with an extending direction of the groove.

For example, the forming the test pad on the base substrate includes: forming a first conducting layer on the base substrate, the first conducting layer including a plurality of parallel conducting strips; and forming an insulating layer of a uniform thickness and a second conducting layer of a uniform thickness on the first conducting layer, the second conducting layer being electrically connected with the first conducting layer through via holes in the insulating layer.

For example, the test pad is formed in a non-display region of the array substrate; a display region of the array substrate includes a gate line, a first protective layer and a pixel electrode which are formed on the base substrate; and the first conducting layer and the gate line are formed at the same time by a same patterning process, the insulating layer and the first protective layer are formed at the same time by a same patterning process, and the second conducting layer and the pixel electrode are formed at the same time by a same patterning process.

For example, the test pad is formed in a non-display region of the array substrate; a display region of the array substrate includes a data line, a second protective layer and a pixel electrode which are formed on the base substrate; and the first conducting layer and the data line are formed at the same time by a same patterning process, the insulating layer and the second protective layer are formed at the same time by a same patterning process, and the second conducting layer and the pixel electrode are formed at the same time by a same patterning process.

For example, the forming the test pad on the base substrate includes: forming a conducting layer on the base substrate; and thinning a partial region of the conducting layer to form the groove.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a schematic view illustrating an array substrate according to embodiments of the present disclosure;

FIG. 2 is a top view of a test pad in FIG. 1;

FIG. 3 is a schematic view illustrating another array substrate according to the embodiments of the present disclosure; and

FIG. 4 is a top view of a test pad in FIG. 3.

### DETAILED DESCRIPTION

In order to clarify the objects, technical solutions and advantages of the present disclosure, the technical solutions of embodiments of the present disclosure will be described in a clearly and fully understandable way in connection with the drawings. It is obvious that the described embodiments are just a part but not all of the embodiments of the disclosure. Based on the described embodiments herein, those skilled in the art can obtain other embodiment(s), without any inventive work, which should be within the scope of the disclosure.

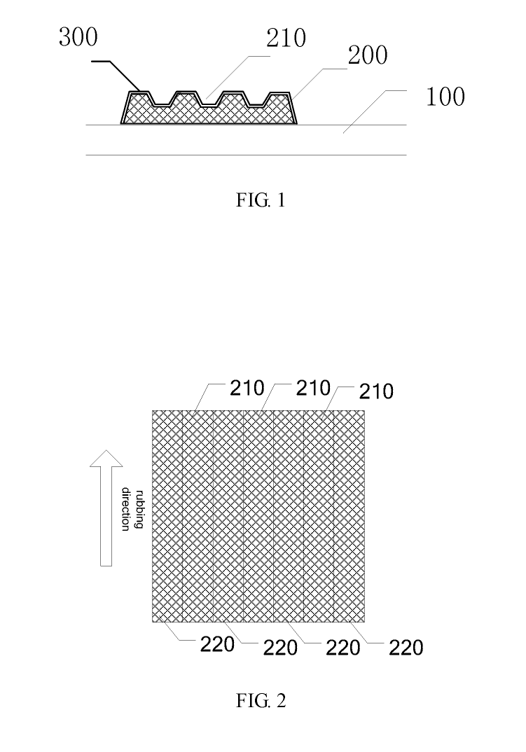

FIG. 1 is an array substrate according to the embodiments of the present disclosure; the array substrate comprises a base substrate 100, and a test pad 200 and an alignment film 300 which are formed on the base substrate 100. For example, the alignment film 300 is formed on the test pad 200, and the alignment film 300 directly or indirectly contacts the test pad 200. A groove 210 is provided on a surface of the test pad 200 and an extending direction of the groove 210 is consistent with a rubbing direction of the alignment film.

Referring to FIG. 2, FIG. 2 is a top view of the test pad in FIG. 1, a plurality of parallel strip protrusions 220 are provided on the surface of the test pad, and the extending direction of the strip protrusions 220 is consistent with the rubbing direction of the alignment film, so that the extending direction of the groove 210 between adjacent protrusions 220 is consistent with the rubbing direction of the alignment film.

As shown in FIG. 1 and FIG. 2, the test pad 200 includes a conducting layer, and a partial region of the conducting layer is thinned to form the groove.

In the array substrate according to the embodiments of the present disclosure, the groove is formed on the surface of the test pad and the extending direction of the groove is consistent with the rubbing direction of the alignment film; in the case that the alignment film is subjected to the rubbing process, damage to the rubbing cloth can be reduced, and thus the rubbing effect can be improved and a service life of the rubbing cloth can be prolonged.

For example, in order to form the above-described test pad, a conducting layer is formed on the base substrate firstly, and then a patterning process is adopted to thin the partial region of the conducting layer, thereby forming the desired groove on the surface of the conducting layer. For example, the test pad is formed in a non-display region of the array substrate; in order to reduce the number of times of patterning process of the array substrate, the test pad is manufactured at the same time of forming a pattern in a display region of the array substrate.

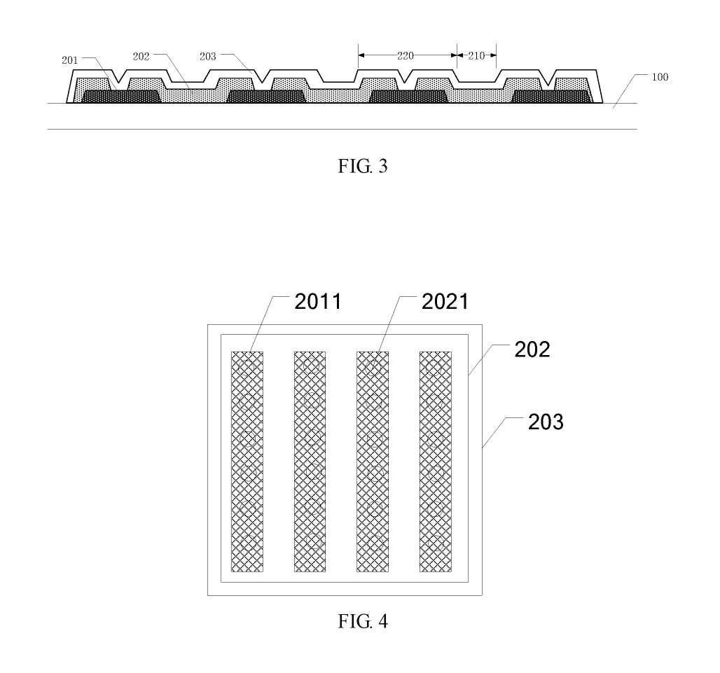

Referring to FIG. 3, FIG. 3 is a schematic view illustrating another array substrate according to the embodiments of the present disclosure. The array substrate comprises a base substrate 100, and a test pad and an alignment film which are formed on the base substrate 100.

For example, the test pad includes a first conducting layer 201, an insulating layer 202 and a second conducting layer 203 which are formed on the base substrate 100, the second conducting layer is electrically connected with the first conducting layer 201 through via holes in the insulating layer 202.

A shown in FIG. 4, the first conducting layer 201 includes a plurality of parallel conducting strips 2011, portions of the insulating layer 202 corresponding to the conducting strips 2011 are provided with via holes 2021, so that the second conducting layer 203 is electrically connected with the first conducting layer 201 through the via holes 2021.

In the test pad, since an extending direction of the conducting strips 2011 in the first conducting layer 201 is consistent with a rubbing direction of the alignment film and a thickness of the insulating layer 202 and a thickness of the second conducting layer 203 are uniform in respective positions, so that a groove with an extending direction is consistent with the rubbing direction of the alignment film is formed on the surface of the test pad.

For example, the conducting strips 2011 are made of metal.

It should be noted that although the alignment film 300 is not shown in FIG. 3 and FIG. 4, the alignment film 300 is similar to that in FIG. 1 and FIG. 2.

For example, for the array substrate in a TN mode, a display region thereof includes a gate electrode (in a same layer as a gate line), a first protective layer (for example, a gate insulating layer), an active layer, a source/drain electrode (in a same layer as a data line), a second protective layer (for example, a passivation layer) and a pixel electrode. For example, the first protective layer covers the gate electrode and the gate line and the second protective layer covers the source/drain electrode and the data line.

In the case that the above-described test pad is configured to test the gate line in the display region of the array substrate, the test pad is connected to the gate line. Regarding the test pad as shown in FIG. 1 and FIG. 2, the test pad and the gate line for example are made of a same material and provided in a same layer. Regarding the test pad as shown in FIG. 3 and FIG. 4, the first conducting layer and the gate line of the display region are connected, made of a same material and provided in a same layer, the insulating layer and the first protective layer of the display region are made of a same material and provided in a same layer, and the second conducting layer and the pixel electrode of the display region are made of a same material and provided in a same layer.

In the case that the above-described test pad is configured to test the data line in the display region of the array substrate, the test pad is connected to the data line. Regarding the test pad as shown in FIG. 1 and FIG. 2, the test pad and the data line are made of a same material and provided in a same layer. Regarding the test pad as shown in FIG. 3 and FIG. 4, the first conducting layer and the data line are made of a same material and provided in a same layer, the insulating layer and the second protective layer are made of a same material and provided in a same layer, and the second conducting layer and the pixel electrode are made of a same material and provided in a same layer.

The embodiments of the present disclosure further provide a display panel, comprising the above-described array substrate.

The embodiments of the present disclosure further provide a display device, comprising the above-described display panel. For example, the display device according to the embodiments of the present disclosure is a laptop display screen, a liquid crystal display, a liquid crystal television, a digital photo frame, a cellphone, a tablet computer or any other product or part with a display function.

The embodiments of the present further provide a manufacturing method of an array substrate, which comprises:

Forming a test pad on a base substrate, wherein a groove is formed on a surface of the test pad; and

Forming an alignment film on the base substrate, wherein a rubbing direction of the alignment film is consistent with an extending direction of the groove.

For example, the forming the test pad on the base substrate includes:

Forming a first conducting layer on the base substrate, the first conducting layer including a plurality of parallel conducting strips; and

Forming an insulating layer of a uniform thickness and a second conducting layer of a uniform thickness on the first conducting layer, the second conducting layer being electrically connected with the first conducting layer through via holes in the insulating layer.

For example, for the array substrate in a TN mode, a display region thereof includes a gate electrode (in a same layer as a gate line), a first protective layer (that is, a gate insulating layer), an active layer, a source/drain electrode (in a same layer as a data line), a second protective layer (that is, a passivation layer) and a pixel electrode. In a process of manufacturing the array substrate of such structure, the test pad for example is manufactured at the same time of forming the above-described pattern in the display region of the array substrate. For example, the first protective layer covers the gate electrode and the gate line, and the second protective layer covers the source/drain electrode and the data line.

For example, at the same time of forming the gate line, the first protective layer and the pixel electrode in the display region of the array substrate, the test pad for testing the gate line is manufactured in a non-display region of the array substrate, so that the first conducting layer and the gate line are formed at the same time by a same patterning process, the insulating layer and the first protective layer are formed at the same time by a same patterning process, and the second conducting layer and the pixel electrode are formed at the same time by a same patterning process.

For example, at the same time of forming the data line, the second protective layer and the pixel electrode in the display region of the array substrate, the test pad for testing the data line is manufactured in the non-display region of the array substrate, so that the first conducting layer and the data line are formed at the same time by a same patterning process, the insulating layer and the second protective layer are formed at the same time by a same patterning process, and the second conducting layer and the pixel electrode are formed at the same time by a same patterning process.

In addition, in a manufacturing process of the above-described test pad, a width of each conducting strip in the first conducting layer is formed as small as possible and the quantity of the conducting strips is increased, thus achieving a better rubbing effect. In addition, an area of the test pad for example is increased according to practical requirements to make up the reduction of a contact area with other structures due to the existence of the groove.

In the manufacturing method of the array substrate according to the embodiments of the present disclosure, the groove is formed on the surface of the test pad and the extending direction of the groove is consistent with the rubbing direction of the alignment film. In the case that the alignment film is subjected to the rubbing process, the groove can contain hair of the extruded rubbing cloth, thus reducing an influence of the test pad on the rubbing cloth, further improving the rubbing and prolonging the service life of the rubbing cloth.

The foregoing embodiments merely are exemplary embodiments of the disclosure, and not intended to define the scope of the disclosure, and the scope of the disclosure is determined by the appended claims.

The application claims priority of Chinese Patent Application No. 201510591070.3 filed on Sep. 16, 2015, the disclosure of which is incorporated herein by reference in its entirety as part of the present application.

1. An array substrate, comprising a base substrate, and a test pad and an alignment film which are formed on the base substrate, wherein,
a groove is provided on a surface of the test pad and an extending direction of the groove is consistent with a rubbing direction of the alignment film.

2. The array substrate according to claim 1, wherein, the test pad includes a first conducting layer, an insulating layer and a second conducting layer which are formed on the base substrate, the second conducting layer is electrically connected with the first conducting layer through via holes in the insulating layer.

3. The array substrate according to claim 2, wherein, the first conducting layer includes a plurality of parallel conducting strips and a thickness of the insulating layer and a thickness of the second conducting layer are uniform, so as to form the groove on the surface of the test pad.

4. The array substrate according to claim 2, wherein,
the test pad is formed in a non-display region of the array substrate;
a display region of the array substrate includes a gate line, a first protective layer and a pixel electrode which are formed on the base substrate; and
the first conducting layer and the gate line are made of a same material and provided in a same layer, the insulating layer and the first protective layer are made of a same material and provided in a same layer, and the second conducting layer and the pixel electrode are made of a same material and provided in a same layer.

5. The array substrate according to claim 4, wherein, the test pad is connected with the gate line and configured to test the gate line.

6. The array substrate according to claim 2, wherein,
the test pad is formed in a non-display region of the array substrate;
a display region of the array substrate includes a data line, a second protective layer and a pixel electrode which are formed on the base substrate; and
the first conducting layer and the data line are made of a same material and provided in a same layer, the insulating layer and the second protective layer are made of a same material and provided in a same layer, and the second conducting layer and the pixel electrode are made of a same material and provided in a same layer.

7. The array substrate according to claim 6, wherein, the test pad is connected with the data line and configured to test the data lines.

8. The array substrate according to claim 1, wherein, the test pad includes a conducting layer, and a partial region of the conducting layer is thinned to form the groove.

9. The array substrate according to claim 8, wherein,
the test pad is formed in a non-display region of the array substrate;
a display region of the array substrate includes a gate line provided on the base substrate; and
the conducting layer and the gate line are made of a same material and provided in a same layer.

10. The array substrate according to claim 9, wherein, the test pad is connected with the gate line and configured to test the gate line.

11. The array substrate according to claim 8, wherein,
the test pad is formed in a non-display region of the array substrate;
a display region of the array substrate includes a data line provided on the base substrate; and
the conducting layer and the data line are made of a same material and provided in a same layer.

12. The array substrate according to claim 11, wherein, the test pad is connected with the data line and configured to test the data line.

13. A display panel, comprising the array substrate according to claim 1.

14. A display device, comprising the display panel according to claim 13.

15. A manufacturing method of an array substrate, comprising:
forming a test pad on a base substrate, wherein a groove is formed on a surface of the test pad; and
forming an alignment film on the base substrate, wherein a rubbing direction of the alignment film is consistent with an extending direction of the groove.

16. The manufacturing method according to claim 15, wherein, the forming the test pad on the base substrate includes:
forming a first conducting layer on the base substrate, the first conducting layer including a plurality of parallel conducting strips; and
forming an insulating layer of a uniform thickness and a second conducting layer of a uniform thickness on the first conducting layer, the second conducting layer being electrically connected with the first conducting layer through via holes in the insulating layer.

17. The manufacturing method according to claim 16, wherein,
the test pad is formed in a non-display region of the array substrate;
a display region of the array substrate includes a gate line, a first protective layer and a pixel electrode which are formed on the base substrate; and
the first conducting layer and the gate line are formed at the same time by a same patterning process, the insulating layer and the first protective layer are formed at the same time by a same patterning process, and the second conducting layer and the pixel electrode are formed at the same time by a same patterning process.

18. The manufacturing method according to claim 16, wherein,
the test pad is formed in a non-display region of the array substrate;
a display region of the array substrate includes a data line, a second protective layer and a pixel electrode which are formed on the base substrate; and
the first conducting layer and the data line are formed at the same time by a same patterning process, the insulating layer and the second protective layer are formed at the same time by a same patterning process, and the second conducting layer and the pixel electrode are formed at the same time by a same patterning process.

19. The manufacturing method according to claim 15, wherein, the forming the test pad on the base substrate includes:
forming a conducting layer on the base substrate; and
thinning a partial region of the conducting layer to form the groove.
